(19) United States
(12) Patent Application Publication
(10) Pub. No.: US 2025/0291969 A1
(43) Pub. Date: Sep. 18, 2025

(54) METHODS AND SYSTEMS FOR GENERATING AN AUTONOMOUS DRIVING SIMULATION SCENARIO

(71) Applicant: HUAWEI TECHNOLOGIES CO., LTD., Shenzhen (CN)

(72) Inventors: Hamidreza FAZLALI, Markham (CA); Mustafa KHAN, Etobicoke (CA); Tongtong CAO, Markham (CA); Dzmitry TSISHKOU, Courbevoie (FR); Dongfeng BAI, Beijing (CN); Bingbing LIU, Beijing (CN)

(21) Appl. No.: 18/605,153

(22) Filed: Mar. 14, 2024

(51) Int. Cl. G06F 30/20; B60W 60/00

(52) U.S. Cl. CPC G06F 30/20; B60W 60/001

(57) ABSTRACT

Systems and methods for computer-implemented method for generating an autonomous driving simulation scenario. The method includes acquiring a set of data points representative of a scene comprising one or more object, each data point being associated with a set of properties, the properties of a given data point being indicative of a type of object to which the given data point belongs, generating a live representation of the scene based on the data points, receiving a set of scenario instructions from a user and generating a driving scenario based on the representation of the scene and the set of scenario instructions.

### FIELD

The present technology relates generally to autonomous vehicles, including methods, apparatuses, systems, and non-transitory computer-readable media for simulation of autonomous driving scenarios.

### BACKGROUND

The proliferation of autonomous vehicles presents the potential for more efficient passenger and cargo movement within transportation networks. Moreover, the integration of autonomous vehicles can lead to enhanced safety features and improved inter-vehicle communication.

However, a significant challenge lies in acquiring a substantial volume of high-quality training data to accurately represent diverse driving conditions and scenarios. This data is indispensable for training machine learning models utilized across various autonomous vehicle subsystems, such as perception, planning, and control. Simply capturing sensor data from autonomous vehicle operations proves insufficient for this purpose. To address this challenge, some approaches have turned to simulation data for model training. For example, certain strategies involve utilizing simulation data generated by simulators resembling video games.

3D reconstruction has the potential to reconstruct and simulate ADS scenes captured in driving logs with a high degree of realism. In recent years, advancements in 3D reconstruction were catalyzed by the development of neural radiance fields (NeRFs), which learns an implicit representation of a scene using fully-connected deep networks and performs novel view synthesis using volume rendering. NeRFs, while realistic, have high computational costs and assume the reconstructed scene is static in nature which complicates their application in ADS contexts with numerous dynamic actors. Neural Scene Graph (NSG), NuSim and UniSim address this by decomposing the scene into a static background and dynamic foreground objects and jointly optimizing several neural fields. NuSim additionally performs multi-sensor simulation and UniSim utilizes the reconstruction in a closed-loop ADS simulator. In contrast to neural field-based methods, 3D Gaussian Splatting (3DGS) is an example of a reconstruction paradigm that explicitly represents a scene using Gaussians, achieving high-quality novel-view synthesis and allowing real-time rendering by splatting these Gaussians onto images.

Nonetheless, one of the drawbacks of this approach is the limited quality and fidelity of the data provided by such simulators, which fails to accurately replicate real-world driving conditions. Thus, while autonomous vehicle technology holds promise for revolutionizing transportation systems, overcoming data acquisition challenges remains crucial for its advancement.

### SUMMARY

Some ray tracing and neural rendering-based techniques, where points are sampled along each ray and the predicted color and density along the ray is accumulated to compute the final Red-Green-Blue (RGB) value for each pixel in an image, are not able to address real-time performance requirements. Given a high-resolution driving scene camera log, this can take a long time (e.g. seconds). Therefore, these methods usually resort to optimizing their point sampling or simplifying the complexity of the implicit models which sacrifices visual quality.

At least some embodiments of the present technology include systems and method for addressing three main drawbacks of current technologies, namely: addressing real-time performance requirement, data accuracy, and driving scenario adjustment provisioning.

In a first broad aspect of the present technology, there is provided a computer-implemented method for generating an autonomous driving simulation scenario. The method includes acquiring a set of data points representative of a scene comprising one or more object, each data point being associated with a set of properties, the properties of a given data point being indicative of a type of object to which the given data point belongs, generating a live representation of the scene based on the data points, receiving a set of scenario instructions from a user and generating a driving scenario based on the representation of the scene and the set of scenario instructions.

In some non-limiting implementations, acquiring the set of data points includes acquiring a sequence of images of a scene and executing a 3D reconstruction pipeline on the sequence of multi-view images to generate the set of data points.

In some non-limiting implementations, executing the 3D reconstruction pipeline includes employing a Structure-From-Motion technique on the sequence of multi-view images.

In some non-limiting implementations, executing a 3D reconstruction pipeline on the sequence of multi-view images to generate the set of data points includes determining presence of at least one object and determining a trajectory of the at least one object.

In some non-limiting implementations, determining a trajectory of the at least one object includes employing at least one of a 3D object detection algorithm, a tracking algorithm or an occupancy-flow algorithm.

In some non-limiting implementations, acquiring the set of data points includes employing a Light Detection and Ranging (LIDAR) system to generate the set of data points.

In some non-limiting implementations, acquiring the set of data points includes randomly initiate the set of data points.

In some non-limiting implementations, acquiring the set of data points includes accessing a point cloud representative of the scene, the set of data points being further based on the accessed point cloud.

In some non-limiting implementations, the representation of the scene is at least one of a sequence of Red-Blue-Green images, a sequence of two-dimensional (2D) semantic/panoptic images, or a sequence of three-dimensional (3D) point clouds.

In some non-limiting implementations, the method further includes, prior to receiving the set of scenario instructions, forming a first set of data points corresponding to entities located in a foreground of the scene, adjusting properties of the first set of data points based on a matching between a type of object associated with the data points of the first set of data points and template simulated objects.

In some non-limiting implementations, the set of scenario instruction comprises identification of a first object to add to the representation of the scene or to remove therefrom.

In some non-limiting implementations, in response to determination being made that the first object is to be added to the representation, generating a driving scenario includes determining a trajectory of the first object within the scene and generating data points representative of the first object based on the trajectory and the scenario instructions.

In some non-limiting implementations, in response to determination being made that the first object is to be added to the representation, generating a driving scenario includes accessing a database storing object model representations, identifying an object model representation based on the set of scenario instructions and adding the object model representation to the live representation.

In some non-limiting implementations, receiving a set of scenario instructions includes receiving a plurality of sets of scenario instructions; and generating a driving scenario includes generating a plurality of driving scenario, each driving scenario being based on a corresponding one of the sets of scenario instructions.

In some non-limiting implementations, generating a live representation of the scene based on the data points includes determining a first set of data points representative of a road section within the scene, determining a second set of data points representative of a rest of the scene, and executing optimization routines to the first and second sets of data points in an independent manner.

In some non-limiting implementations, determining a first set of data points representative of a road section comprises applying a pre-determined mask an execute a plane fitting operation to data points that are included in the applied pre-determined mask.

In some non-limiting implementations, the method further includes, for a given object identified in the scene, employing a neural network to update a dynamic appearance of the given object in the representation of the scene, the neural network being configured to receive a temporal embedding of data points representative of the given object, color features of the data points representative of the given object, and position features of the data points representative of the given object.

In some non-limiting implementations, generating a live representation of the scene based on the data points includes determining a first set of data points representative of a first object and applying a chroma-key pruning to the first object by setting color features of data points located in a vicinity of the first object to pre-determined color features, and discarding the data points located in a vicinity of the first object whose color features correspond to the pre-determined color features.

In some non-limiting implementations, each data point is associated with a semantic feature, the method further including applying semantic pruning to the first object by discarding the data points located in a vicinity of the first object whose semantic features correspond to semantic features of data points representative of the first object.

In some non-limiting implementations, each object is associated with a rigidity category being either rigid or non-rigid and the method further includes for each non-rigid object, determining a plurality of rigid sub-objects forming the non-rigid object and generating a live representation of the scene based on the data points comprises determining a pose of the plurality of rigid sub-objects.

In some non-limiting implementations, generating a live representation of the scene based on the data points includes determining a first set of data points representative of a first object, determining a main axis of the first object, generating a second set of data points, each data point of the second set of data points being a reflection of a given data points of the first set respectively to the main axis and defining the first object as being represented by a combination of the first and second sets of data points.

In a second broad aspect of the present technology, there is provided an apparatus for generating an autonomous driving simulation scenario. The apparatus may include a controller and a memory storing a plurality of executable instructions which, when executed by the controller, cause the apparatus to acquire a set of data points representative of a scene comprising one or more object, each data point being associated with a set of properties, the properties of a given data point being indicative of a type of object to which the given data point belongs, generate a live representation of the scene based on the data points, receive a set of scenario instructions from a user and generate a driving scenario based on the representation of the scene and the set of scenario instructions.

In some non-limiting implementations, the apparatus acquires the set of data points by acquiring a sequence of images of a scene and executing a 3D reconstruction pipeline on the sequence of multi-view images to generate the set of data points.

In some non-limiting implementations, the apparatus executes the 3D reconstruction pipeline by employing a Structure-From-Motion technique on the sequence of multi-view images.

In some non-limiting implementations, the apparatus executes a 3D reconstruction pipeline on the sequence of multi-view images to generate the set of data points by determining presence of at least one object and determining a trajectory of the at least one object.

In some non-limiting implementations, the apparatus determines a trajectory of the at least one object by employing at least one of a 3D object detection algorithm, a tracking algorithm or an occupancy-flow algorithm.

In some non-limiting implementations, the apparatus acquires the set of data points by employing a Light Detection and Ranging (LIDAR) apparatus to generate the set of data points.

In some non-limiting implementations, the apparatus acquires the set of data points by randomly initiate the set of data points.

In some non-limiting implementations, the apparatus acquires the set of data points by accessing a point cloud representative of the scene, the set of data points being further based on the accessed point cloud.

In some non-limiting implementations, the representation of the scene is at least one of a sequence of Red-Blue-Green images, a sequence of two-dimensional (2D) semantic/panoptic images, or a sequence of three-dimensional (3D) point clouds.

In some non-limiting implementations, the apparatus is further configured to, prior to receiving the set of scenario instructions, form a first set of data points corresponding to entities located in a foreground of the scene and adjust properties of the first set of data points based on a matching between a type of object associated with the data points of the first set of data points and template simulated objects.

In some non-limiting implementations, the set of scenario instruction comprises identification of a first object to add to the representation of the scene or to remove therefrom.

In some non-limiting implementations, in response to determination being made that the first object is to be added to the representation, the apparatus generates a driving scenario by determining a trajectory of the first object within the scene and generating data points representative of the first object based on the trajectory and the scenario instructions.

In some non-limiting implementations, in response to determination being made that the first object is to be added to the representation, the apparatus generates a driving scenario by accessing a database storing object model representations, identifying an object model representation based on the set of scenario instructions and adding the object model representation to the live representation.

In some non-limiting implementations, the apparatus is further configured to receive a plurality of sets of scenario instructions upon receiving a set of scenario instructions and generate a plurality of driving scenario, each driving scenario being based on a corresponding one of the sets of scenario instructions upon generating a driving scenario.

In some non-limiting implementations, the apparatus generates a live representation of the scene based on the data points by determining a first set of data points representative of a road section within the scene, determining a second set of data points representative of a rest of the scene and executing optimization routines to the first and second sets of data points in an independent manner.

In some non-limiting implementations, upon determining a first set of data points representative of a road section, the apparatus is configured to apply a pre-determined mask an execute a plane fitting operation to data points that are included in the applied pre-determined mask.

In some non-limiting implementations, the apparatus is further configured to, for a given object identified in the scene, employ a neural network to update a dynamic appearance of the given object in the representation of the scene, the neural network being configured to receive a temporal embedding of data points representative of the given object, color features of the data points representative of the given object, and position features of the data points representative of the given object.

In some non-limiting implementations, the apparatus is further configured to, upon generating a live representation of the scene based on the data points, determine a first set of data points representative of a first object and apply a chroma-key pruning to the first object by setting color features of data points located in a vicinity of the first object to pre-determined color features, and discarding the data points located in a vicinity of the first object whose color features correspond to the pre-determined color features.

In some non-limiting implementations, each data point is associated with a semantic feature, the apparatus being further configured to apply semantic pruning to the first object by discarding the data points located in a vicinity of the first object whose semantic features correspond to semantic features of data points representative of the first object.

In some non-limiting implementations, each object is associated with a rigidity category being either rigid or non-rigid, the apparatus being further configured to for each non-rigid object, determine a plurality of rigid sub-objects forming the non-rigid object and generate a live representation of the scene based on the data points comprises determining a pose of the plurality of rigid sub-objects.

In some non-limiting implementations, the apparatus is further configured to, upon generating a live representation of the scene based on the data points, determine a first set of data points representative of a first object, determine a main axis of the first object, generate a second set of data points, each data point of the second set of data points being a reflection of a given data points of the first set respectively to the main axis and define the first object as being represented by a combination of the first and second sets of data points.

According to a third aspect, a computer storage medium is provided. The computer storage medium stores program code, and the program code is used to execute one or more instructions for the method according to the first aspect or any one of the possible embodiments of the first aspect, or the second aspect or any one of the possible embodiments of the second aspect.

According to a fourth aspect, this application provides a computer program product including one or more instructions, where when the computer program product runs on a computer, the computer performs the method according to the first aspect or any one of the possible embodiments of the first aspect, or the second aspect or any one of the possible embodiments of the second aspect.

According to a fifth aspect, this application provides a non-transitory computer-readable medium storing instruction the instructions causing a processor in a device to implement the method according to the first aspect or any one of the possible embodiments of the first aspect, or the second aspect or any one of the possible embodiments of the second aspect.

According to a sixth aspect, this application provides a device configured to perform the method according to the first aspect or any one of the possible embodiments of the first aspect, or the second aspect or any one of the possible embodiments of the second aspect.

According to a seventh aspect, this application provides a processor, configured to execute instructions to cause a device to perform the method according to the first aspect or any one of the possible embodiments of the first aspect, or the second aspect or any one of the possible embodiments of the second aspect.

According to a eighth aspect, this application provides an integrated circuit configure to perform the method according to the first aspect or any one of the possible embodiments of the first aspect, or the second aspect or any one of the possible embodiments of the second aspect.

In the context of the present specification, a “server” is a computer program that is running on appropriate hardware and is capable of receiving requests (e.g., from devices) over a network, and carrying out those requests, or causing those requests to be carried out. The hardware may be one physical computer or one physical computer apparatus, but neither is required to be the case with respect to the present technology. In the present context, the use of the expression a “server” is not intended to mean that every task (e.g., received instructions or requests) or any particular task will have been received, carried out, or caused to be carried out, by the same server (i.e., the same software and/or hardware); it is intended to mean that any number of software elements or hardware devices may be involved in receiving/sending, carrying out or causing to be carried out any task or request, or the consequences of any task or request; and all of this software and hardware may be one server or multiple servers, both of which are included within the expression “at least one server”.

In the context of the present specification, “device” is any computer hardware that is capable of running software appropriate to the relevant task at hand. Thus, some (non-limiting) examples of devices include personal computers (desktops, laptops, netbooks, etc.), smartphones, and tablets, as well as network equipment such as routers, switches, and gateways. It should be noted that a device acting as a device in the present context is not precluded from acting as a server to other devices. The use of the expression “a device” does not preclude multiple devices being used in receiving/sending, carrying out or causing to be carried out any task or request, or the consequences of any task or request, or steps of any method described herein.

In the context of the present specification, a “database” is any structured collection of data, irrespective of its particular structure, the database management software, or the computer hardware on which the data is stored, implemented or otherwise rendered available for use. A database may reside on the same hardware as the process that stores or makes use of the information stored in the database or it may reside on separate hardware, such as a dedicated server or plurality of servers. It can be said that a database is a logically ordered collection of structured data kept electronically in a computer system.

In the context of the present specification, the expression “information” includes information of any nature or kind whatsoever capable of being stored in a database. Thus, information includes, but is not limited to audiovisual works (images, movies, sound records, presentations etc.), data (location data, numerical data, etc.), text (opinions, comments, questions, messages, etc.), documents, spreadsheets, lists of words, etc.

In the context of the present specification, the expression “component” is meant to include software (appropriate to a particular hardware context) that is both necessary and sufficient to achieve the specific function(s) being referenced.

In the context of the present specification, the expression “computer usable information storage medium” is intended to include media of any nature and kind whatsoever, including RAM, ROM, disks (CD-ROMs, DVDs, floppy disks, hard drivers, etc.), USB keys, solid state-drives, tape drives, etc.

In the context of the present specification, the words “first”, “second”, “third”, etc. have been used as adjectives only for the purpose of allowing for distinction between the nouns that they modify from one another, and not for the purpose of describing any particular relationship between those nouns. Thus, for example, it should be understood that, the use of the terms “first server” and “third server” is not intended to imply any particular order, type, chronology, hierarchy or ranking (for example) of/between the server, nor is their use (by itself) intended imply that any “second server” must necessarily exist in any given situation. Further, as is discussed herein in other contexts, reference to a “first” element and a “second” element does not preclude the two elements from being the same actual real-world element. Thus, for example, in some instances, a “first” server and a “second” server may be the same software and/or hardware, in other cases they may be different software and/or hardware.

Implementations of the present technology each have at least one of the above-mentioned object and/or aspects, but do not necessarily have all of them. It should be understood that some aspects of the present technology that have resulted from attempting to attain the above-mentioned object may not satisfy this object and/or may satisfy other objects not specifically recited herein.

Additional and/or alternative features, aspects and advantages of implementations of the present technology will become apparent from the following description, the accompanying drawings and the appended claims.

### BRIEF DESCRIPTION OF THE DRAWINGS

For a better understanding of the present technology, as well as other aspects and further features thereof, reference is made to the following description which is to be used in conjunction with the accompanying drawings, where:

FIG. 1 illustrates an example of a computing device that may be used to implement any of the methods described herein.

FIG. 2 illustrates a driving scenario generation pipeline in accordance with some non-limiting implementations of the present technology.

FIG. 3 illustrates modules of the driving scenario generation pipeline of FIG. 2 in accordance with some non-limiting implementations of the present technology

FIG. 4 illustrates a pipeline for reconstructing rigid synthetic objects in accordance with some non-limiting implementations of the present technology

FIG. 5 illustrates a pipeline for reconstructing rigid real objects in accordance with some non-limiting implementations of the present technology.

FIG. 6 illustrates pipelines for semantic-based pruning and chroma-key & semantic-based pruning of a 3D point cloud and in accordance with some non-limiting implementations of the present technology.

FIG. 7 illustrates a pipeline for reconstruction of non-rigid, real/synthetic objects in accordance with some non-limiting implementations of the present technology.

FIG. 8 illustrates a Structure-from-Motion-based scene reconstruction pipeline in accordance with some non-limiting implementations of the present technology.

FIG. 9 illustrates a LiDAR-based scene reconstruction pipeline in accordance with some non-limiting implementations of the present technology.

FIG. 10 illustrates a pipeline for initializing and pruning data points in distant regions of a scene in accordance with some non-limiting implementations of the present technology.

FIG. 11 illustrates a pipeline for combining and finetuning data points representative of objects and scene in accordance with some non-limiting implementations of the present technology

FIG. 12 illustrates a pipeline for editing driving scenario using scene completion in accordance with some non-limiting implementations of the present technology

FIG. 13 is a scheme-block illustration of a method executed by a processor of the computing device of FIG. 1, in accordance with at least some non-limiting embodiments of the present technology.

FIG. 14 is a schematic diagram of a computing architecture for modeling dynamic appearance of objects in accordance with at least some non-limiting embodiments of the present technology.

FIG. 15 illustrates a pipeline for generating additional reflected data points in accordance with at least some non-limiting embodiments of the present technology.

### DETAILED DESCRIPTION

The examples and conditional language recited herein are principally intended to aid the reader in understanding the principles of the present technology and not to limit its scope to such specifically recited examples and conditions. It will be appreciated that those skilled in the art may devise various arrangements which, although not explicitly described or shown herein, nonetheless embody the principles of the present technology and are included within its spirit and scope.

Furthermore, as an aid to understanding, the following description may describe relatively simplified implementations of the present technology. As persons skilled in the art would understand, various implementations of the present technology may be of a greater complexity.

In some cases, what are believed to be helpful examples of modifications to the present technology may also be set forth. This is done merely as an aid to understanding, and, again, not to define the scope or set forth the bounds of the present technology. These modifications are not an exhaustive list, and a person skilled in the art may make other modifications while nonetheless remaining within the scope of the present technology. Further, where no examples of modifications have been set forth, it should not be interpreted that no modifications are possible and/or that what is described is the sole manner of implementing that element of the present technology.

Moreover, all statements herein reciting principles, aspects, and implementations of the present technology, as well as specific examples thereof, are intended to encompass both structural and functional equivalents thereof, whether they are currently known or developed in the future. Thus, for example, it will be appreciated by those skilled in the art that any block diagrams herein represent conceptual views of illustrative circuitry embodying the principles of the present technology. Similarly, it will be appreciated that any flowcharts, flow diagrams, state transition diagrams, pseudo-code, and the like represent various processes which may be substantially represented in computer-readable media and so executed by a computer or processor, whether or not such computer or processor is explicitly shown.

The functions of the various elements shown in the figures, including any functional block labeled as a “processor”, may be provided through the use of dedicated hardware as well as hardware capable of executing software in association with appropriate software. When provided by a processor, the functions may be provided by a single dedicated processor, by a single shared processor, or by a plurality of individual processors, some of which may be shared. In some embodiments of the present technology, the processor may be a general purpose processor, such as a central processing unit (CPU) or a processor dedicated to a specific purpose, such as a digital signal processor (DSP). Moreover, explicit use of the term a “processor” should not be construed to refer exclusively to hardware capable of executing software, and may implicitly include, without limitation, application specific integrated circuit (ASIC), field programmable gate array (FPGA), read-only memory (ROM) for storing software, random access memory (RAM), and non-volatile storage. Other hardware, conventional and/or custom, may also be included.

Software modules, or simply modules which are implied to be software, may be represented herein as any combination of flowchart elements or other elements indicating performance of process steps and/or textual description. Such modules may be executed by hardware that is expressly or implicitly shown. Moreover, it should be understood that module may include for example, but without being limitative, computer program logic, computer program instructions, software, stack, firmware, hardware circuitry or a combination thereof which provides the required capabilities.

With these fundamentals in place, we will now consider some non-limiting examples to illustrate various implementations of aspects of the present technology.

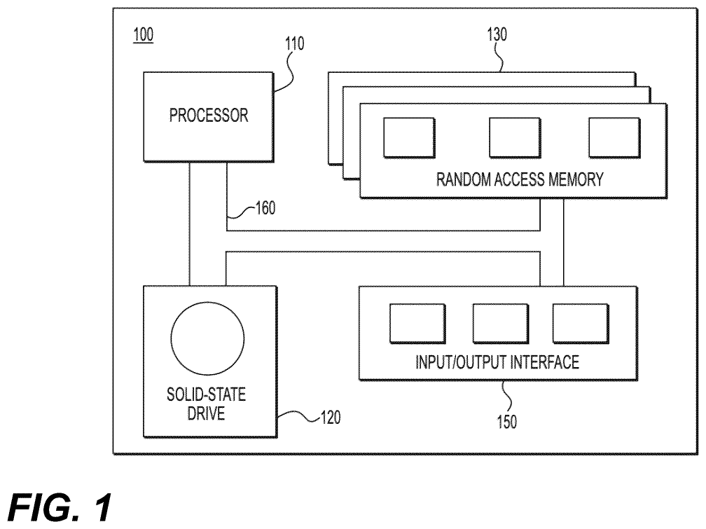

FIG. 1 illustrates a diagram of a computing environment 100 in accordance with an embodiment of the present technology is shown. In some embodiments, the computing environment 100 may be implemented by any of a conventional personal computer, a computer dedicated to operating and/or monitoring systems relating to a data center, a controller and/or an electronic device (such as, but not limited to, a mobile device, a tablet device, a server, a controller unit, a control device, a monitoring device etc.) and/or any combination thereof appropriate to the relevant task at hand. In some embodiments, the computing environment 100 comprises various hardware components including one or more single or multi-core processors collectively represented by a processor 110, a solid-state drive 120, a random access memory 130 and an input/output interface 150.

In some embodiments, the computing environment 100 may also be a sub-system of one of the above-listed systems. In some other embodiments, the computing environment 100 may be an “off the shelf” generic computer system. In some embodiments, the computing environment 100 may also be distributed amongst multiple systems. The computing environment 100 may also be specifically dedicated to the implementation of the present technology. As a person in the art of the present technology may appreciate, multiple variations as to how the computing environment 100 is implemented may be envisioned without departing from the scope of the present technology.

Communication between the various components of the computing environment 100 may be enabled by one or more internal and/or external buses 160 (e.g. a PCI bus, universal serial bus, IEEE 1394 “Firewire” bus, SCSI bus, Serial-ATA bus, ARINC bus, etc.), to which the various hardware components are electronically coupled.

The input/output interface 150 may allow enabling networking capabilities such as wire or wireless access. As an example, the input/output interface 150 may comprise a networking interface such as, but not limited to, a network port, a network socket, a network interface controller and the like. Multiple examples of how the networking interface may be implemented will become apparent to the person skilled in the art of the present technology. For example, but without being limitative, the networking interface may implement specific physical layer and data link layer standard such as Ethernet, Fibre Channel, Wi-Fi or Token Ring. The specific physical layer and the data link layer may provide a base for a full network protocol stack, allowing communication among small groups of computers on the same local area network (LAN) and large-scale network communications through routable protocols, such as Internet Protocol (IP).

According to implementations of the present technology, the solid-state drive 120 stores program instructions suitable for being loaded into the random access memory 130 and executed by the processor 110 for generating driving scenarios for Autonomous Driving Systems (ADS). For example, the program instructions may be part of a library or an application.

In some embodiments of the present technology, the computing environment 100 may be implemented as part of a cloud computing environment. Broadly, a cloud computing environment is a type of computing that relies on a network of remote servers hosted on the internet, for example, to store, manage, and process data, rather than a local server or personal computer. This type of computing allows users to access data and applications from remote locations, and provides a scalable, flexible, and cost-effective solution for data storage and computing. Cloud computing environments can be divided into three main categories: Infrastructure as a Service (IaaS), Platform as a Service (PaaS), and Software as a Service (SaaS). In an IaaS environment, users can rent virtual servers, storage, and other computing resources from a third-party provider, for example. In a PaaS environment, users have access to a platform for developing, running, and managing applications without having to manage the underlying infrastructure. In a SaaS environment, users can access pre-built software applications that are hosted by a third-party provider, for example. In summary, cloud computing environments offer a range of benefits, including cost savings, scalability, increased agility, and the ability to quickly deploy and manage applications.

In the context of the present technology, the processor 110 may be configured to receive input data and generate driving scenarios based on said input. Broadly, the processor 110 may be part of a driving scenario generating system and is configured to execute one or more computer-implemented methods designed to ameliorate conventional driving scenario generating techniques.

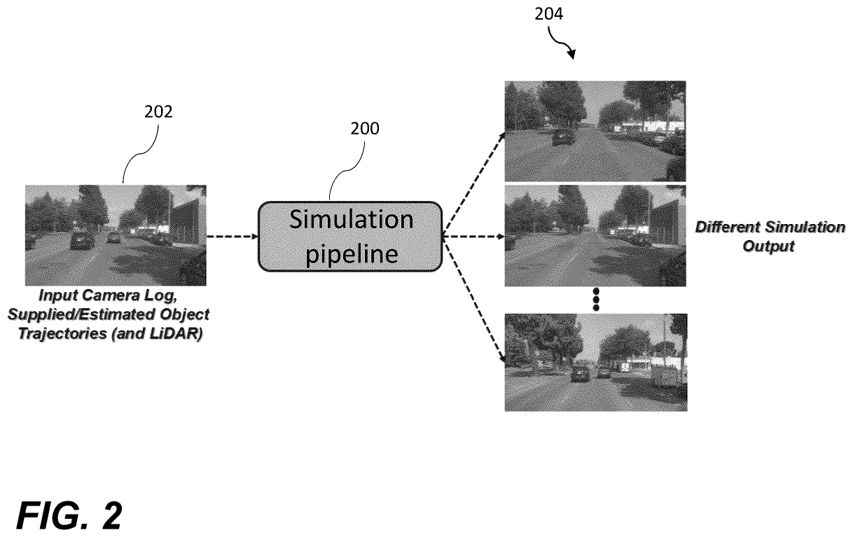

With reference to FIG. 2, there is depicted a driving scenario generation pipeline 200 executable by the computing device 100, in accordance with at least some embodiments of the present technology. It is contemplated that the driving scenario generation pipeline 200 may be implemented by other computer systems that are configured to perform scenario generation for ADS, without departing from the scope of the present technology.

Broadly speaking, the driving scenario generation pipeline 200 receives, in use, an input 202 and may generate one or more driving scenarios as an output 204. It should be noted that a plurality of different driving scenarios may be generated from the same input 202. Differences between the driving scenarios are described in greater detail herein after.

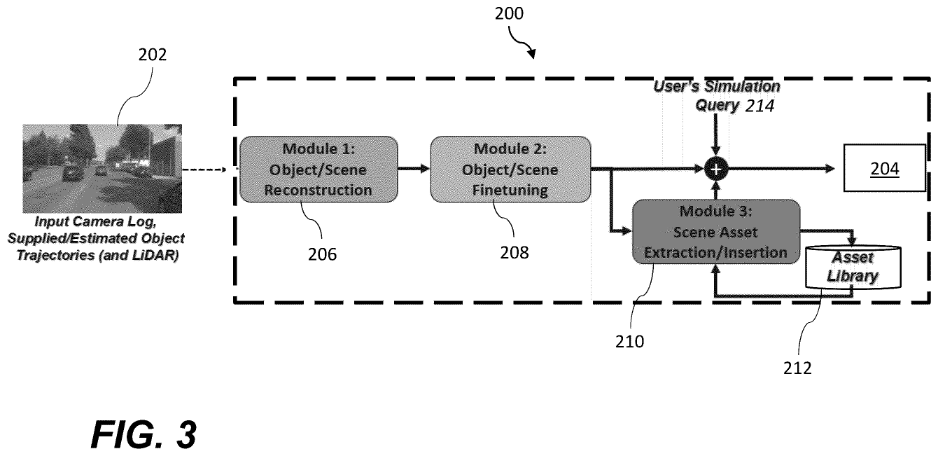

More specifically, and with reference to FIG. 3, the driving scenario generation pipeline 200 includes a reconstruction module 206 that receives the input 202. In some implementations, the input 202 includes a sequence of images (e.g. a camera log) representative of a scena and objects within the scene. A point of view of the images of the scene may correspond to an ego-vehicle hosting an image capturing device (e.g. a camera) that captured the sequence of images. Information about trajectories may also be provided in the input 202 (e.g. three dimensional (3D) bounding boxes). In the same or other implementations, a sequence of 3D point clouds may also be used as the input 202. For example, a given 3D point cloud may have been captured by a calibrated and synchronized LiDAR sensor.

Alternatively, the processor 110 may generate a sparse 3D point cloud and used as an input of the reconstruction module 206. For example, the processor 110 may use a Structure-from-Motion (SfM)-based method such as COLMAP to do so.

In the context of the present disclosure, 3D point clouds includes a plurality of “super points (SP)”, or simply data points, each data point being associated with a set of specific features. Those features include position (e.g. XYZ coordinates), scale (i.e. size), rotation, visual features (appearance (RGB, texture, reflections, luminosity, specular properties, etc.), semantic features (panoptic, language, etc.), opacity features (transparency/density), motion feature (static or dynamic depending if the corresponding object the data points represent is moving or not relatively to the world coordinates) and additional transformation features (e.g. pose corrections, camera exposure estimation, camera extrinsic/intrinsic parameter correction, etc.).

The data points may also be associated with data indicative of a type of object they represent, a type of object they represent. For example, a given object may be rigid (e.g. a car), or non-rigid, namely portions of the object are allowed to move relatively to one another (e.g. a pedestrian). A given object may also be rigid or synthetic. A given data point may be two-dimensional (2D) gaussian splatting, a 3D gaussian splatting, an explicit triangle-based representation, or any other suitable format.

The driving scenario generation pipeline 200 further includes a fine-tuning module 208 executed to fine-tune the appearance of the data points so that different objects (foreground/background) can interact and can create realistic renderings. The driving scenario generation pipeline 200 may also further include an extraction/insertion module 210 communicably connected to a database 212, or “asset library” 212. As will be described in greater detail herein after, the extraction/insertion module 210 may be used to insert objects in a simulated scene and/or remove objects from a simulated scene. Extracted objects may be stored in the asset library 212 and objects such as template objects may also be retrieved from the asset library 212 and inserted in any arbitrary scene to generate a new driving scenario in the output.

In some implementations, the driving scenario generation pipeline 200 may receive user instructions 214 from a user device indicative of characteristic of a driving scenario expected by a user. The driving scenario generation pipeline 200. Outputs of the fine-tuning module 208 and the extraction/insertion module 210 may be adjusted based on user instructions 214 to generate a driving scenario in the output 204. It should be noted that a plurality of different driving scenarios may be generated based on the same input 202.

Broadly speaking, the reconstruction module 206 may reconstruct rigid objects using several multi-view images from a single/few-shot 3D reconstruction methods or CAD models. The resulting data points may be pruned using semantic features and/or visual features. As will be described in greater details herein after, the non-rigid objects may also be reconstructed by identifying a plurality of rigid bodies forming the non-rigid object and estimating their 3D pose in the scene.

In the context of the present disclosure, a scene is a collection of several static objects and, given that objects composing the scene are stationary, the data points representing the scene can be optimized in world coordinates. In some implementations, the dynamic data points are optimized in a canonical coordinate space and then transformed to world coordinates based on an optimized, estimated/supplied transformation. The static data points that constitute the scene require an initial estimate of their locations in world coordinates and so can be reconstructed from camera images and SfM and/or Multi-View-Stereo (MVS) approaches or using LiDAR point clouds. Finally, depending on the nature of images provided in the input 202, the dynamic data points being optimized may be reconstructed to appear synthetic or realistic.

The data points may also be initialized with additional properties that can be optimized by the reconstruction module 106, such as semantic/panoptic information obtained from off-the-shelf 2D/3D segmentation methods. Static data points may have an optical flow property as well which can be optimized based on the ground-truth optical flow (e.g. the sequence of images of the input 202). In some implementations, a change in the position of each data point when rendered between consecutive images may be used by the processor 110 to generate said optical flow.

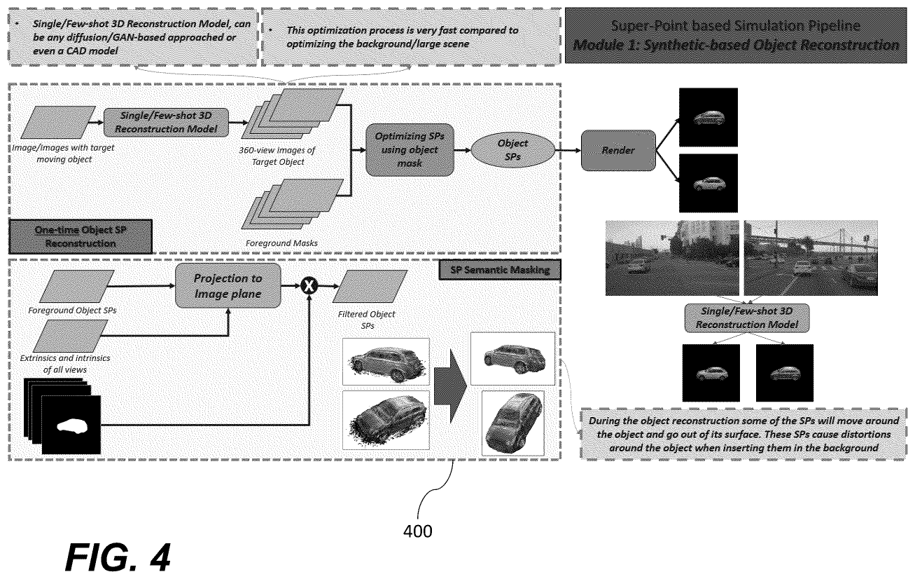

Reconstruction of rigid synthetic object will now be described with reference to FIG. 4. In some implementations, the processor 110 employs multi-view images from single/few-shot 3D reconstruction methods. Said methods may for example include employing diffusion-based networks such as Point-E or DreamFusion, employing Generative Adversarial Networks (GANs) such as nerf-from-image network or progressive-3d-learning network, or employing generated computer-aided design (CAD) models amongst other options which are capable of generating point clouds or meshes that represent the rigid, synthetic object that are to be reconstructed. The position (e.g. the XYZ coordinates) of the data points of each object of the scene may thus be initialized and multi-view images of the object as well as semantic masks of the object may be stored in order to optimize the reconstruction.

Multi-view images and semantic masks of the object are used in order to optimize the data points. There are two ways of using this to reconstruct the object:
If the positions of data points corresponding to the synthetic objects are frozen and no additional points are added or removed during optimization, then the object may be reconstructed with sufficiently high quality (e.g. based for example on Peak Signal-to-Noise ratio or Structural Similarity Index Measure) and in a relatively short period of time.
If the positions of data points corresponding to the synthetic objects are allowed to change and additional points are added or removed during optimization, then the number of data points representing the object may increase and the quality (e.g. based for example on Peak Signal-to-Noise ratio or Structural Similarity Index Measure) may also improve. In order to cleanly isolate the object from potential noise, a semantic masking pipeline 400 may be executed. More specifically, where the positions of data points are projected to an image plane and any data point centers falling out of the semantic mask of the object are discarded, or “pruned”. This cleanly isolate the data points of the object, removes surrounding distortions and prepares the synthetic object for a potential insertion into a scene.

Rigid real objects may also be reconstructed by the reconstruction module 206 using realistic, multi-view images and a semantic and chroma-key pruning approach to cleanly isolate the object's data points during reconstruction.

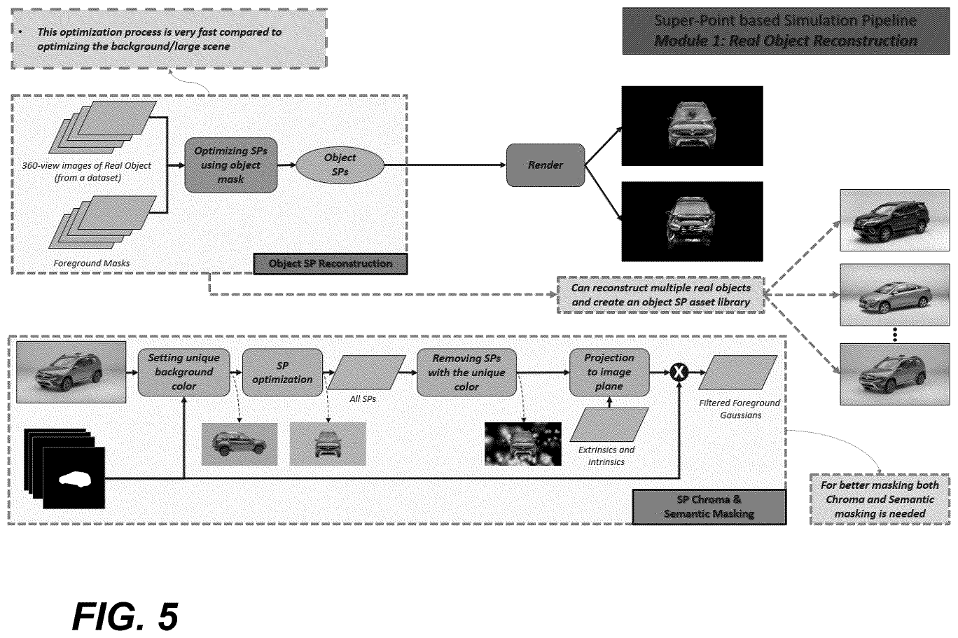

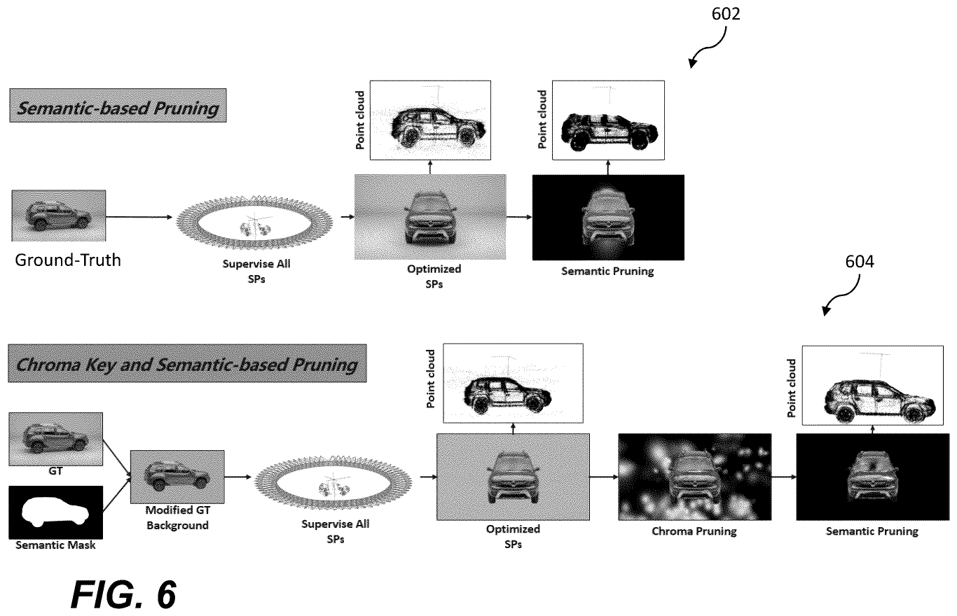

Color or chroma keying is a visual-effect and post-production technique used for isolating and compositing multiple images based on color hues (i.e. chroma range). With reference to FIGS. 5 and 6, the processor 110 may modify the multi-view images provided during optimization, the data points surrounding an object can be forced to reconstruct an arbitrary and unique color. Then, data points that have reconstructed this color can be identified and discarded, or “pruned”. Semantic masking of data points clears any remaining data points with the unique color. As shown in FIG. 5, this approach reconstructs realistic objects and isolates them so they can be inserted into any scene. An ablation is shown in FIG. 6, motivating the need for chroma key and semantic-based pruning when reconstructing realistic objects as it produces visually superior results than simply using semantic-based pruning of data points.

In the context of the present disclosure, a rigid body, such as a car, is an idealization of a body that does not deform or change shape or in which such deformation is negligible. Also, in the context of the present disclosure, non-rigid bodies are capable of deforming and can be reinterpreted as a collection of a plurality of rigid sub-bodies where each sub-body has its own associated pose relatively to one another. Given multi-view images of a non-rigid object and semantic masks, non-rigid synthetic/real bodies can also be reconstructed using the aforementioned approaches. To finetune the data points of such non-rigid real/synthetic objects, a fine-tuning module 208 shown on FIG. 3 and further described herein after may be utilized.

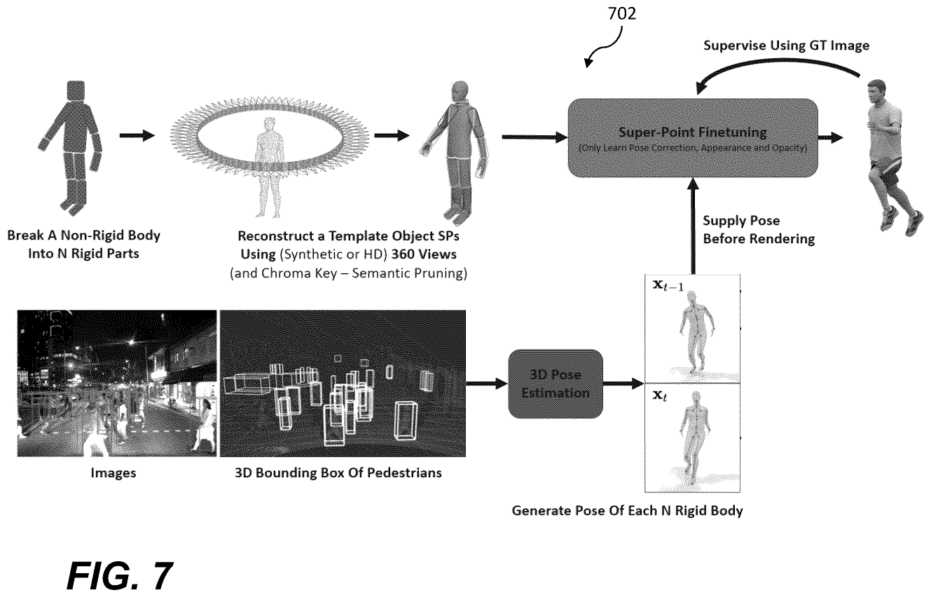

However, an additional pose operation to estimate the pose of each of the plurality of rigid bodies that the non-rigid body is comprised of may be performed upon executing the fine-tuning module 208. For example, a 3D pose estimation network can be employed in order to reconstruct a pedestrian as shown in FIG. 7 through a pipeline 702. In addition to a learned/supplied global position of such a non-rigid object, the pose of each of the N rigid bodies will need to be learned/supplied in order to finetune the appearance of the data points of the non-rigid object by optimizing the pose correction, appearance features, and opacity properties of the data points.

Reconstruction of a given scene may be performed using, for example, Structure-From-Motion (SfM)-based methods and/or using LIDAR data points. In the context of the present disclosure, an ADS scene may be composed of several objects, roads, buildings, traffic lights, and other details to be reconstructed. Sparse point clouds from SfM-based methods or LiDAR sensor may be employed in order to reconstruct such a scene.

However, optimizing the static data points that make up the scene on the ground truth images may be insufficient. More specifically, the reconstructed road data points may have a relatively high thickness and may cause the scene to occlude the dynamic data points when they are placed into the scene. Additionally, there is no constraint that encourages the static data points to learn a realistic geometry for the road. Road markings may thus appear distorted and unrealistic.

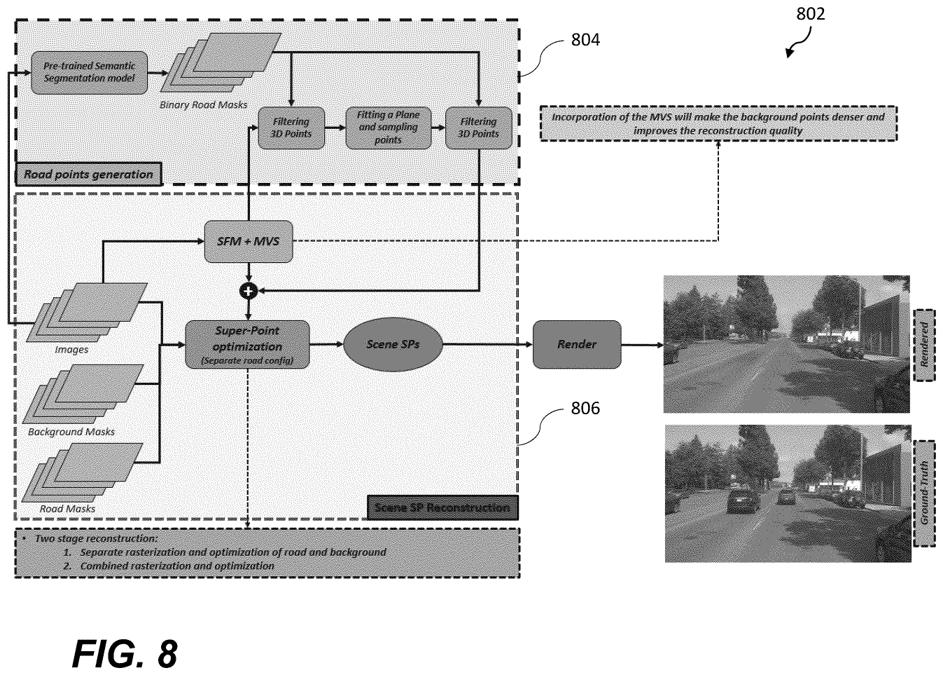

To solve this issue, the fine-tuning module 208 may execute a pipeline 802 shown on FIG. 8. More specifically, data points 804 representative of the road section are separated from the remainder of the data points 806 representative of the scene. To do so when using SfM-based methods, a road mask may be applied, and a plane may be fitted through the location of the data points that fall within this mask. The locations of the data points on this plane are automatically sampled and initialized as a separate, dense set of road data points 804. Next, a two-stage optimization procedure may be executed. First, the road data points and the remaining scene data points are separately rasterized and optimized for a certain number of iterations. Second, the road data points and background data points are combined and their appearance properties are optimized. Furthermore, the data points of the road may be constrained to be geometrically accurate by enforcing its scale and rotation to have a relatively small dimension, be flat, and perpendicular to a normal of a road surface.

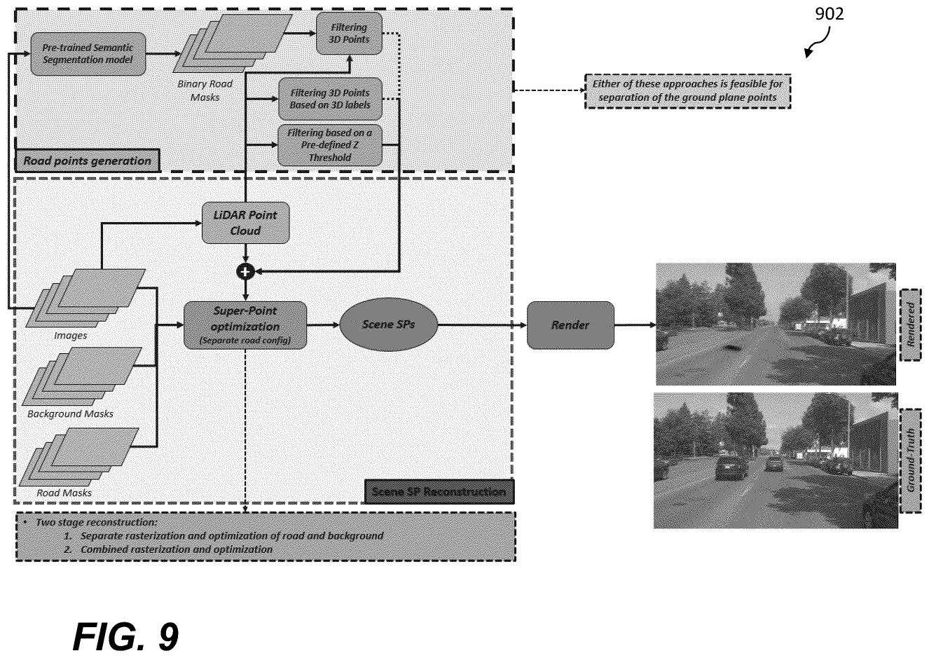

A similar pipeline 902 may also be executed on data points initialized using LiDAR points, as shown on FIG. 9. For LiDAR points, the road points can be separated from the background by running a pre-trained semantic/panoptic segmentation model on the camera image at each frame and then projecting LiDAR points from each frame to the corresponding semantic/panoptic image captured at the time. Then, all the points that have the semantic label of the road may be separated from the remainder of the background. Alternative methods include using a pre-defined height-threshold in order to isolate the road points from the remainder of the scene. The reconstruction procedure may be the same as described relatively to SfM-based Scene Reconstruction.

Therefore, it can be said that large background/scene may be reconstructed by initializing the data points using the SfM/LiDAR point clouds and separating them into road data points and background data points using the semantic labels or a pre-defined height filter or by fitting a road-planc.

However, reconstructing objects in distant regions of a scene may be challenging. This is due, at least in part, to sparsity of the data points initialized from SfM/LiDAR-based methods. Developers of the present technology hare devised methods where additional data points may be automatically added during scene reconstruction to the distant region. The location properties, scale, rotation and appearance properties may further be adjusted upon being added to the scene.

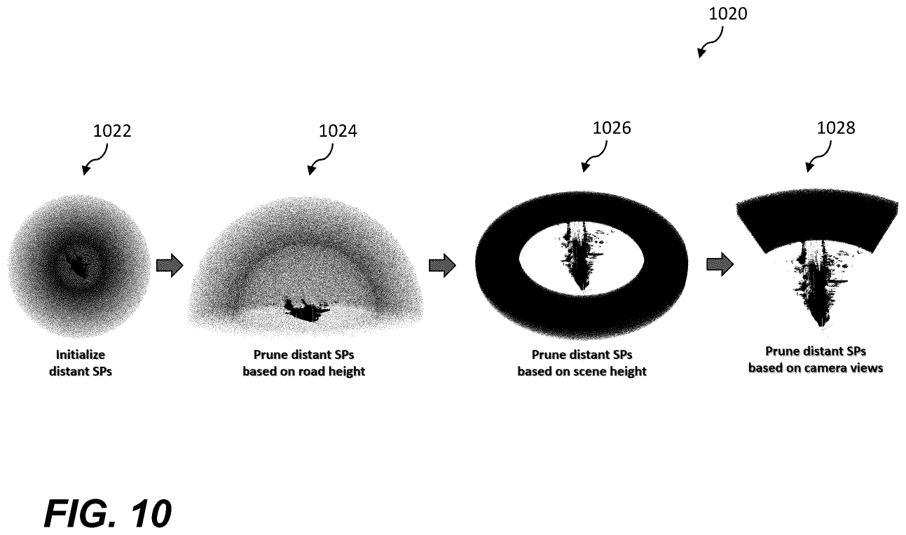

More specifically, FIG. 10 shows a pipeline 1020 for initializing data points for distant region in accordance with some implementations of the present technology. The pipeline 1020 starts by initializing a sphere of additional data points (e.g. randomly) with high density around the scene. The pipeline 1020 continues with pruning some of the additional data points based on a road-height (e.g. a horizon line) at operation 1024, a scene-height at operation 1026, and camera views retrieved from the sequence of images at operation 1028. Additional data points remaining after the pruning operation may further be used to reconstruct the distant region. The density and number of additional data points may vary based on a required quality (e.g. instructed by the user).

The pipeline 1020 may be executed before optimization of the additional data points is executed. A width of the sphere of additional data points may be determined based on a ratio threshold of a scene extent and a density of data points. In the same or other implementations, pruning based on opacity may be executed on the distant region data points to eliminate unneeded and low opacity data points from the scene.

Referring back to FIG. 1, a fine-tuning module 208 may be executed subsequent to the reconstruction module 206. Broadly speaking, the fine-tuning module 208 may be executed to fine-tune the appearance of the data points so that different objects (foreground/background) can interact and can create realistic renderings. For instance, the moving objects (foreground) identified by the reconstruction module 206 may be considered the same as template objects. Therefore, the appearance of these objects can get fine-tuned to match the corresponding ground-truth (GT) objects. In other words, the processor 110 may determine template objects such as Computer-Aided-Design (CAD) objects that corresponds to objects within the scene. The template objects may further be adjusted to fit the corresponding objects within the scene.

Once the data points representative of objects and data points representative of the scene have been reconstructed, they may be combined and rendered together. To prevent misalignment in the pose of the object and distortions around edged of the data points representative of objects from occurring, real/template objects that were reconstructed may be dynamically moved through the scene by providing a trajectory. On the other hand, real/synthetic objects can be fine-tuned so their reconstructed appearance matches the objects shown in the captured driving logs (i.e. the input 202) and then these objects' dynamic movement can be simulated by learning/supplying a trajectory.

Reconstructed realistic objects may be placed into appropriate locations in the scene based on supplied pose of the object in world coordinates. These trajectories can be acquired using annotations in a dataset, using pre-trained 3D object detection and tracking frameworks or point-tracking approaches, or optimizing/estimating a pose or deformation field per timestep during reconstruction. Since the object is realistic, it can be directly placed into the scene and the remainder of the scene can be fine-tuned using a semantic mask which doesn't include the realistic object. Therefore, appearance features of the data points representative of the scene properties may vary during fine-tuning while the data points representative of the object may remain fixed.

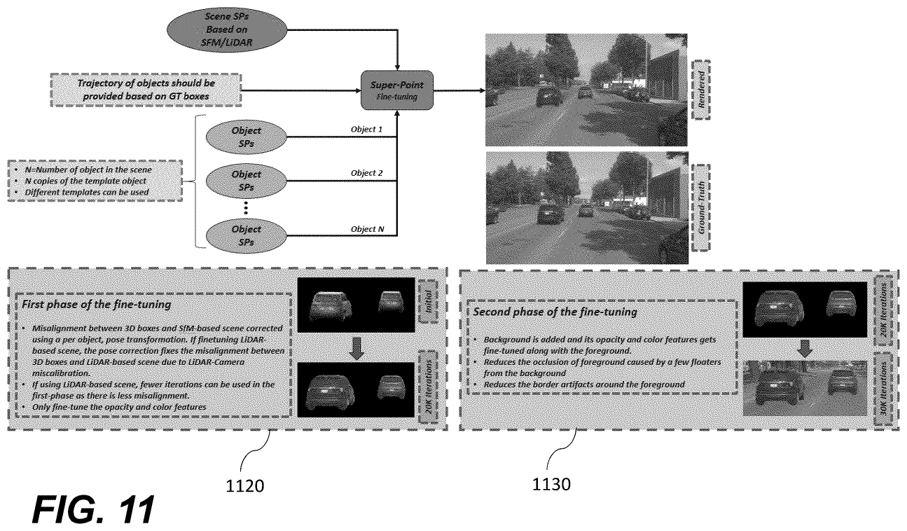

Appearance features of data points representative of synthetic objects may be fine-tuned to resemble the objects in the original scene as shown in FIG. 11. To do so, a plurality (denoted N) of copies of these objects in the scene and move the corresponding data points to the correct location in world coordinates based on learned/supplied trajectory information. In some implementations, the semantic/panoptic or optical flow property of data points may also be computed and optimized during fine-tuning.

As shown on FIG. 11, a first stage 1120 of the fine-tuning executed by the fine-tuning module 208 includes using a semantic mask of the object to supervise an optimization of a pose correction and the appearance features of the data points representative of the object. The pose correction may be estimated in order to overcome potential misalignment between a reconstructed SfM-based or reconstructed LiDAR-based scene and the object pose due to imprecise trajectories/3D bounding boxes information as well as Camera-LiDAR miscalibration errors.

A second stage 1130 of fine-tuning executed by the fine-tuning module 208 includes adding the data points representative of the remaining scene alongside data points representative of the object. Opacity and appearance features of the data points may be fine-tuned using the entire image. This reduces the occlusion of the data points representative of the object by floaters in the scene and also reduces border artifacts in those data points. In the first stage 1120 of fine-tuning, the recovery of finer details can be performed by supplying additional data points that were not initially present and fine-tuning their scale, rotation and opacity properties.

In some implementations, reconstruction of shadows of the objects may be optimized by supplying a series of data points below a lower plane of a car. Potential distortions induced by adding those series of data points may be cleared during the second stage 1140.

On another aspect, it should be noted that the appearance of an object may undergo variations based on the conditions present in the autonomous driving environment. Objects in motion experiencing direct sunlight, shadows, or adverse weather conditions may exhibit distinct appearances. Moreover, dynamic objects surrounding an autonomous vehicle may engage turn signals, activate brake lights, flash hazard lights to indicate danger, or illuminate external lights like those on ambulances and police cars, along with other visual cues. The present technology provides methods for accurately simulating these appearance changes.

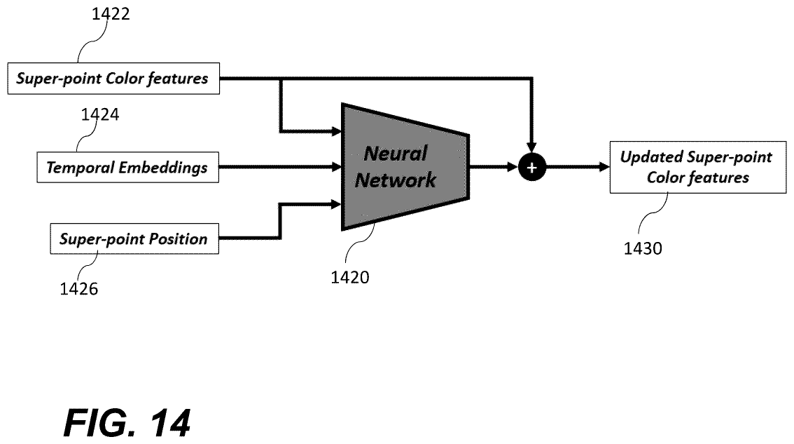

With reference to FIG. 14, there is shown a neural network (NN) 1420 for modelling evolving appearance of dynamic objects. More specifically, the NN 1420 is configured to incorporate both temporal characteristics and neural network associations with data points representative of a given object. The NN 1420 may learn residual appearance features at each time step to transform static appearance features of the given object into dynamic appearance features. In some implementations, the NN 1420 includes fully connected layers. The inputs to the NN1420 includes current data points color features 1422, their spatial coordinates 1426 in the canonical coordinate system, and a distinct, per-frame learnable embedding 1424. Throughout the optimization process, the NN 1420 learns how to add residual features to the original data point color features, taking into account the time step and location, thus accommodating appearance changes in each frame by providing updated data point color feature 1430. Consequently, this approach enables the dynamic modelling of appearance alterations in various objects within the scene, contingent upon the location of their data points and the temporal progression.

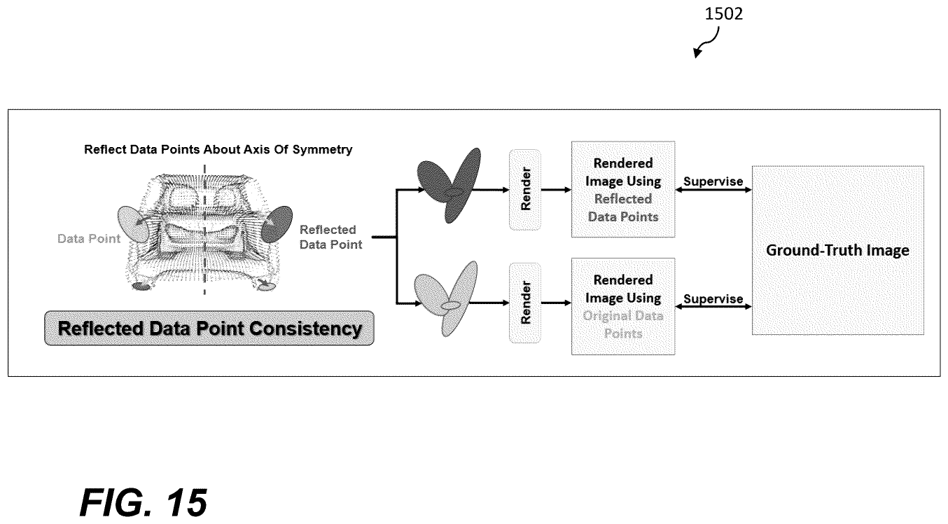

During foreground fine-tuning, optimizing data points representative of a foreground of a given object with limited camera views may result in a noticeable decrease in appearance quality during novel view synthesis, such as when the ego-vehicle changes lanes. To address this issue, an optimization pipeline 1502, shown on FIG. 15, may be used, relying on structural symmetry of foreground objects that such object often exhibits.

The optimization pipeline aims at ensuring symmetrical consistency among data points representing two symmetrical sides of a foreground object. More specifically, for a given foreground object, the corresponding data points, or “foreground data points”, are identified. A symmetry axis is further determined for that foreground object. In use, the processor 110 may set a pre-defined axis as an axis of symmetry, or automatically compute it. In this latter case, an axis of symmetry of a foreground object may be found in the intersection of the sets of directions which zero gradients of each of moment functions of the given object.

In use, a second set of data points, or “reflected data points”, is thus generated for the given foreground object, each data point of the second set of data points being a reflection of a given data points of the first set respectively to the main axis. The foreground object being therefore defined as being represented by a combination of the initial data points and the second set of data points. Broadly speaking, the rendered image, created using both the initial data points and the reflected “data points”, may then be optimized alongside the ground-truth views. This approach enables the supervision of all data points of foreground objects including originally occluded data points, under challenging viewing angles. Consequently, the data points can converge to the correct geometry and appearance, enhancing the overall quality of the reconstruction.

Referring back to FIG. 1, an extraction/insertion module 210 may be executed subsequent to the fine-tuning module 208. Broadly speaking, the extraction/insertion module 210 may be executed to perform scene editing, enabling the extraction of data points from scenes, accumulation of data point-based assets in an asset library 212, and insertion of data points into new scenes to generate novel scenarios.

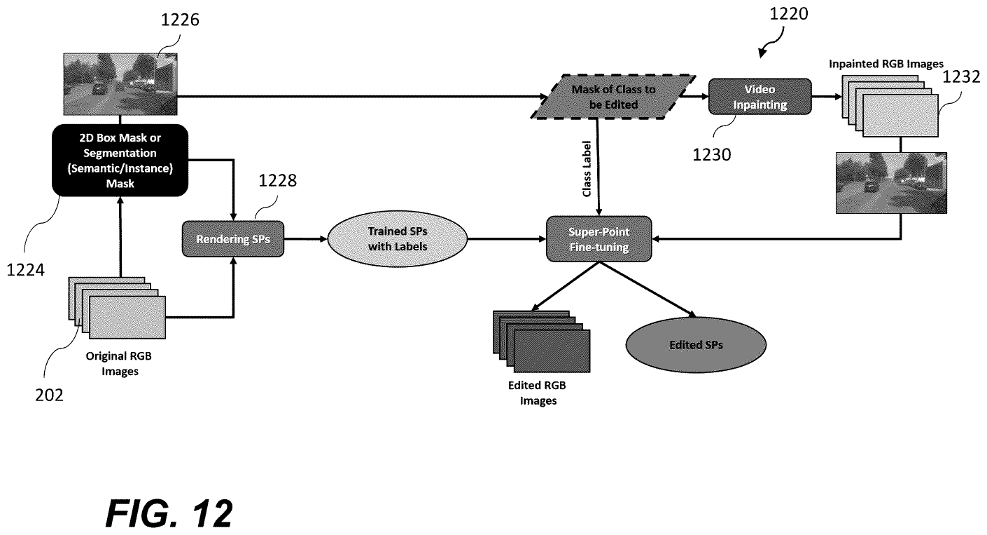

In some implementations, extraction of a specific object in a scene relies on semantic properties of data points or 3D bounding box information of the object. Data points representing an object may thus be extracted and added to an asset library for usage in simulation. Extraction from an existing scene may cause distortions once the object is removed. FIG. 12 illustrates a pipeline 1120 to mitigate the effect of these distortions, which utilizes video-inpainting or scene completion approaches to alter the ground-truth images (e.g. the input 202) so that the removed object is not present. Then, reconstructing the scene or fine-tuning a reconstructed scene with these modified images may remove any existing distortions from the reconstruction with the extracted/removed object by modifying the data points of the removed objects to complete the scene according to inpainted images.

For insertion of data points into an existing or new scene, a trajectory generation module that creates realistic, kinematically feasible trajectories may be executed. Secondly, features of data points representative of the object may be translated or rotated and their lighting, color or appearance features to vary their appearance slightly if needed.

Finally, the pipeline 1120 may be used in order to simulate new scenarios. For instance, static objects such as a barricade may be inserted into a scene in order to block the ego-vehicle and see whether it halts appropriately. Dynamic objects such as a car incoming towards the ego-vehicle can also be inserted to assess how the ADS handles safety-critical scenarios.

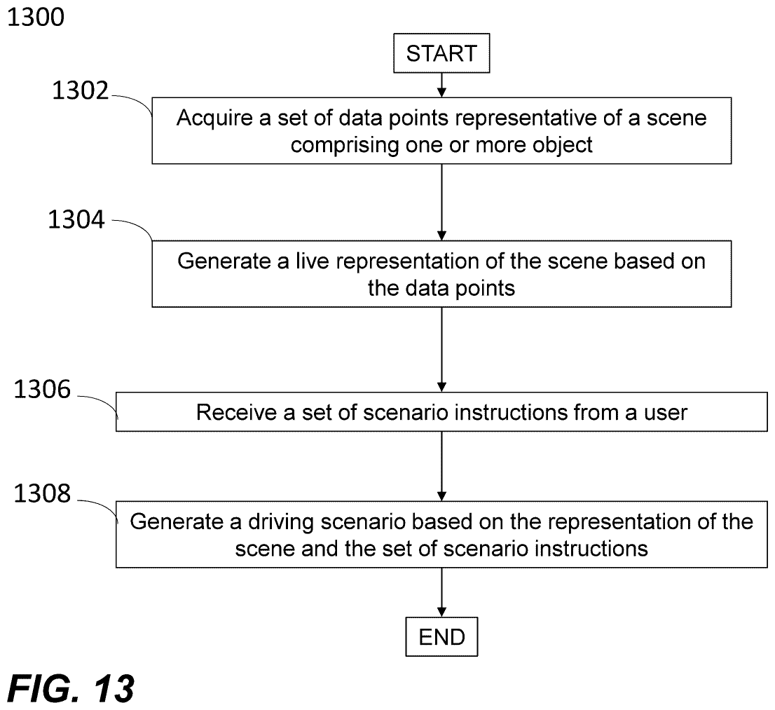

In some embodiments of the present technology, the processor 110 is configured to execute a method 1300 for generating an autonomous driving simulation scenario. In some implementations, the given object is at least one of a text-based object, an audio object, and a video object. A scheme-block illustration of operations of the method 1300 is depicted in FIG. 13. It is contemplated that the method 1300 can be executed by an electronic device implemented similarly to what has been described above with reference to FIG. 1. In some implementations, one or more steps of the method 1300 may be executed by more than one physical processors. For example, more than one physical processors may be communicatively coupled over a network for performing one or more steps in a distributed manner. It is therefore contemplated that one or more steps from the method 1300 may be executed by distinct electronic devices, without departing from the scope of the present technology.

The method 1300 starts with acquiring, at operation 1302, a set of data points representative of a scene comprising one or more object, each data point being associated with a set of properties, the properties of a given data point being indicative of a type of object to which the given data point belongs.

In some implementations, the set of data points are acquired by acquiring a sequence of images of a scene and executing a 3D reconstruction pipeline on the sequence of multi-view images to generate the set of data points. For example, the 3D reconstruction pipeline may be executed by employing a Structure-From-Motion technique on the sequence of multi-view images. In the same or other examples, the 3D reconstruction pipeline is executed on the sequence of multi-view images to generate the set of data points by determining presence of at least one object and determining a trajectory of the at least one object.

In the same or other implementations, determining a trajectory of the at least one object includes employing at least one of a 3D object detection algorithm, a tracking algorithm or an occupancy-flow algorithm.

In alternative implementations, acquiring the set of data points may include employing a Light Detection and Ranging (LIDAR) system to generate the set of data points. In yet alternative implementations, acquiring the set of data points includes randomly initiate the set of data points. In yet other alternative implementations, acquiring the set of data points may include accessing a point cloud representative of the scene, the set of data points being further based on the accessed point cloud.

The method 1300 continues with generating, at operation 1304, a live representation of the scene based on the data points. For example, the representation of the scene may be at least one of a sequence of Red-Blue-Green images, a sequence of two-dimensional (2D) semantic/panoptic images, or a sequence of three-dimensional (3D) point clouds.

The method 1300 continues with receiving, at operation 1306, receiving a set of scenario instructions from a user.

The method continues with generating, at operation 1308, a driving scenario based on the representation of the scene and the set of scenario instructions. The set of scenario instruction may include, for example, identification of a first object to add to the representation of the scene or to remove therefrom. In some implementations, in response to determination being made that the first object is to be added to the representation, generating a driving scenario includes determining a trajectory of the first object within the scene and generating data points representative of the first object based on the trajectory and the scenario instructions.

Generating a live representation of the scene based on the data points may include determining a first set of data points representative of a first object and applying a chroma-key pruning to the first object by setting color features of data points located in a vicinity of the first object to pre-determined color features, and discarding the data points located in a vicinity of the first object whose color features correspond to the pre-determined color features.

For example, generating a live representation of the scene based on the data points may include determining a first set of data points representative of a road section within the scene, determining a second set of data points representative of a rest of the scene, and executing optimization routines to the first and second sets of data points in an independent manner. In some implementations, determining a first set of data points representative of a road section comprises applying a pre-determined mask an execute a plane fitting operation to data points that are included in the applied pre-determined mask.

In the same or other implementations, in response to determination being made that the first object is to be added to the representation, the method 1300 includes generating a driving scenario includes accessing a database storing object model representations, identifying an object model representation based on the set of scenario instructions and adding the object model representation to the live representation.

In the same or other implementations, generating a live representation of the scene based on the data points includes determining a first set of data points representative of a first object, determining a main axis of the first object, generating a second set of data points, each data point of the second set of data points being a reflection of a given data points of the first set respectively to the main axis and defining the first object as being represented by a combination of the first and second sets of data points.

In some implementations, the method 1300 further includes, prior to receiving the set of scenario instructions, forming a first set of data points corresponding to entities located in a foreground of the scene, adjusting properties of the first set of data points based on a matching between a type of object associated with the data points of the first set of data points and template simulated objects.

In the same or other implementations, receiving a set of scenario instructions includes receiving a plurality of sets of scenario instructions; and generating a driving scenario includes generating a plurality of driving scenario, each driving scenario being based on a corresponding one of the sets of scenario instructions.

In some implementations, the method 1300 further includes, for a given object identified in the scene, employing a neural network to update a dynamic appearance of the given object in the representation of the scene, the neural network being configured to receive a temporal embedding of data points representative of the given object, color features of the data points representative of the given object, and position features of the data points representative of the given object.

In the same of other implementations, each data point is associated with a semantic feature, the method further including applying semantic pruning to the first object by discarding the data points located in a vicinity of the first object whose semantic features correspond to semantic features of data points representative of the first object.

In the same or other implementations, each object may be associated with a rigidity category being either rigid or non-rigid. The method 1300 may further include, for each non-rigid object, determining a plurality of rigid sub-objects forming the non-rigid object and generating a live representation of the scene based on the data points comprises determining a pose of the plurality of rigid sub-objects.

While the above-described implementations have been described and shown with reference to particular operations performed in a particular order, it will be understood that these steps may be combined, sub-divided, or re-ordered without departing from the teachings of the present technology. At least some of the steps may be executed in parallel or in series. Accordingly, the order and grouping of the steps is not a limitation of the present technology.

While the primary application of the technology described in the present disclosure is ADS, it may be used and extended to various other domains, including robotics, cinematography, visual effects, advertising, military applications, AR/VR, construction, real estate (for planning, buying, selling), and medical scene/image 3D reconstruction, among others, wherein camera images (and/or LiDAR data points) serve as inputs. This proposed technology demonstrates capability in swiftly and realistically reconstructing and simulating scenarios featuring static backgrounds and dynamic actors.

Modifications and improvements to the above-described implementations of the present technology may become apparent to those skilled in the art. The foregoing description is intended to be exemplary rather than limiting. The scope of the present technology is therefore intended to be limited solely by the scope of the appended claims.

1. A computer-implemented method for generating an autonomous driving simulation scenario, the method comprising:
acquiring a set of data points representative of a scene comprising one or more objects, each data point being associated with a set of properties, the properties of a given data point being indicative of a type of object to which the given data point belongs;
generating a live representation of the scene based on the data points;
receiving a set of scenario instructions from a user; and
generating a driving scenario based on the representation of the scene and the set of scenario instructions.

2. The method of claim 1, wherein acquiring the set of data points comprises:
acquiring a sequence of images of a scene; and
executing a 3D reconstruction pipeline on the sequence of multi-view images to generate the set of data points.

3. The method of claim 2, wherein executing the 3D reconstruction pipeline comprises employing a Structure-From-Motion technique on the sequence of multi-view images.

4. The method of claim 2, wherein executing a 3D reconstruction pipeline on the sequence of multi-view images to generate the set of data points comprises:
determining presence of at least one object; and
determining a trajectory of the at least one object.

5. The method of claim 4, wherein determining a trajectory of the at least one object comprises employing at least one of a 3D object detection algorithm, a tracking algorithm or an occupancy-flow algorithm.

6. The method of claim 1, wherein acquiring the set of data points comprises accessing a point cloud representative of the scene, the set of data points being further based on the accessed point cloud.

7. The method of claim 1, further comprising, prior to receiving the set of scenario instructions:
forming a first set of data points corresponding to entities located in a foreground of the scene;
adjusting properties of the first set of data points based on a matching between a type of object associated with the data points of the first set of data points and template simulated objects.

8. The method of claim 1, wherein the set of scenario instruction comprises identification of a first object to add to the representation of the scene or to remove therefrom.

9. The method of claim 1, wherein:
receiving a set of scenario instructions comprises receiving a plurality of sets of scenario instructions; and
generating a driving scenario comprises generating a plurality of driving scenario, each driving scenario being based on a corresponding one of the sets of scenario instructions.

10. The method of claim 1, wherein generating a live representation of the scene based on the data points comprises:
determining a first set of data points representative of a road section within the scene;
determining a second set of data points representative of a rest of the scene;
executing optimization routines to the first and second sets of data points in an independent manner.

11. An apparatus for generating an autonomous driving simulation scenario, the apparatus comprising a controller and a memory storing a plurality of executable instructions which, when executed by the controller, cause the apparatus to:
acquire a set of data points representative of a scene comprising one or more object, each data point being associated with a set of properties, the properties of a given data point being indicative of a type of object to which the given data point belongs;
generate a live representation of the scene based on the data points;
receive a set of scenario instructions from a user; and
generate a driving scenario based on the representation of the scene and the set of scenario instructions.

12. The apparatus of claim 11, wherein the apparatus acquires the set of data points by:
acquiring a sequence of images of a scene; and
executing a 3D reconstruction pipeline on the sequence of multi-view images to generate the set of data points.

13. The apparatus of claim 12, wherein the apparatus executes the 3D reconstruction pipeline by employing a Structure-From-Motion technique on the sequence of multi-view images.

14. The apparatus of claim 12, wherein the apparatus executes a 3D reconstruction pipeline on the sequence of multi-view images to generate the set of data points by:
determining presence of at least one object; and
determining a trajectory of the at least one object.

15. The apparatus of claim 11, further configured to, prior to receiving the set of scenario instructions:
form a first set of data points corresponding to entities located in a foreground of the scene; and
adjust properties of the first set of data points based on a matching between a type of object associated with the data points of the first set of data points and template simulated objects.

16. The apparatus of claim 11, wherein the set of scenario instruction comprises identification of a first object to add to the representation of the scene or to remove therefrom.

17. The apparatus of claim 11, further configured to:
receive a plurality of sets of scenario instructions upon receiving a set of scenario instructions; and
generate a plurality of driving scenario, each driving scenario being based on a corresponding one of the sets of scenario instructions upon generating a driving scenario.

18. The apparatus of claim 11, further configured to, upon generating a live representation of the scene based on the data points:
determine a first set of data points representative of a first object; and
apply a chroma-key pruning to the first object by:
setting color features of data points located in a vicinity of the first object to pre-determined color features, and
discarding the data points located in a vicinity of the first object whose color features correspond to the pre-determined color features.

19. The apparatus of claim 11, wherein each object is associated with a rigidity category being either rigid or non-rigid, the apparatus being further configured to:
for each non-rigid object, determine a plurality of rigid sub-objects forming the non-rigid object; and
generate a live representation of the scene based on the data points comprises determining a pose of the plurality of rigid sub-objects.

20. A non-transitory computer-readable medium storing instruction the instructions causing a processor in a device to implement the method of claim 1.
